(19) United States
(12) Patent Application Publication
(10) Pub. No.: US 2010/0000589 A1
(43) Pub. Date: Jan. 7, 2010

(54) Photovoltaic devices having conductive paths formed through the active photo absorber

(75) Inventor: Zoltan Joseph Kiss, Belle Mead, NJ (US)

Correspondence Address: Amelio Solar, Inc., 200 LudlowDrive, Suite C, Ewing, NJ, 08638, US

(73) Assignee: Amelio Solar, Inc.

(21) Appl. No.: 12/217,280

(22) Filed: Jul. 3, 2008

(51) Int. Cl. H01L 31/042; B05D 5/12

(52) U.S. Cl. 136/244; 427/76

(57) ABSTRACT

A solar PV module comprises an array of serially interconnected spaced PV solar cells on a common substrate, each cell comprising a 1^{st} electrode on said substrate, an active PV film on the 1^{st} electrode, a 2^{nd} electrode, at least one of said electrodes being light transmitting and wherein the 2^{nd} electrode of the nth solar cell of the array is connected to the 1^{st} electrode of the succeeding, (n+1)th cell of the array via a portion of PV film which has a substantially higher conductivity than the remainder of the PV film. The novel structure of the present invention is achieved by substantially increasing the conductivity of a continuous light absorbing PV film in the area of desired electrical contact by doping the film in the desired areas.

### FIELD OF THE INVENTION

This invention relates to large area photovoltaic (PV) solar devices and a method of making such devices.

### BACKGROUND OF THE INVENTION

The single cell voltage of most solar cells is too low to be directly usable or efficient for many applications. For example, the single cell voltage of a copper-indium-gallium-diselenide (CuInₓGa₁₋ₓSe₂, or CIGS for short) material ranges between 0.5 and 0.8 volts depending on the composition of the CIGS material (the absorber of the solar cell).

A great advantage of thin film photovoltaic (PV) processing technology, compared to traditional crystalline silicon wafer based PV module manufacturing processing, is the opportunity of monolithic integration of individual solar cells, on the same substrate used for the fabrication of solar cells over large areas, without resorting to the cumbersome and laborious cell connections (in series and/or parallel) practiced in the industrial production of large area crystalline Si PV modules.

In manufacturing PV modules, single cells are connected in series to obtain a high voltage suitable for different applications. Typically, the output voltage of a PV module might range between 10 to 100 volts, depending on the number of cells interconnected in series.

FIG. 1 illustrates a conventional series interconnect scheme for an amorphous silicon (a-Si:H) PV module made by removal of semiconductor film to produce an array of individual series connected cells. The interconnection usually takes place in the manufacturing process by interconnecting a front transparent conductive layer 10 (front contact), e.g. tin oxide, of a first cell to a back conductive layer 12, e.g. aluminum, of an adjoining cell. These layers are encapsulated between two pieces of glass 14 and 16, respectively. The semiconductor Si film 18 (the p-i-n layers) which lies adjacent to and between the conductive layers 10 and 12 of the module is cut out by, e.g. laser scribe, to expose the SnO₂ front contact 10, to allow the subsequently deposited back contact films of the n+1th cell to be directly in contact with the front contact of the adjacent nth cell. In this way, the individual cells of the array are serially connected so as to increase the output voltage of the module. Typically, the module is sealed from the atmosphere by means of a sealant 19, such as ethylene vinyl acetate (EVA) which also bonds the front and back glass substrates 14 and 16.

Another conventional device module employing CIGS PV films is shown in FIG. 2. In these devices, where light falls on the device from the side opposite to a supporting plate 21, the aim is to connect a transparent conductive oxide (TCO), e.g. a zinc oxide (ZnO), front electrode 20 of the nth cell to the molybdenum (Mo) back electrode 22 of the n+1th cell. The series interconnection of individual cells usually takes place by using laser or mechanical processes whereby the different thin films and different cells are separated by removing a narrow line of the various thin film materials. In a conventional CIGS PV device of the structure glass/Mo/CIGS/buffer/ZnO, three scribing steps would take place, respectively at positions A, B, and C (see FIG. 2 for illustration), to create isolation lines in the Mo layer 22, CIGS film 24, and CIGS/buffer/ZnO layers 20. The first and the last scribing steps are needed to create individual (electrically separated) cells on the same substrate, while the 2^{nd} scribe (for the removal of the CIGS film to expose the Mo film) is the critical procedure to allow adjacent cells to be electrically connected in series (monolithic integration of solar cells).

Also, the ZnO front contact (and TCO thin films generally, including SnO₂ for a-Si based PV modules) is conventionally isolated by scribing techniques such as laser ablation and mechanical scratch. This method can damage the CIGS semiconductive thin films, and the material in the ‘cut’ grooves likely is inferior. Debris left in the isolation trenches often causes shorts that degrade the power output of such PV devices. The buffer indicated above (not shown in the figure) is an optional, but generally preferred layer. It may comprise a very thin film of high resistivity ZnO (HR ZnO) or an n-type semiconductor, e.g. n-type CdS which forms a junction with the p-type CIGS absorber film. Other useful buffer materials include ZnS and CdZnS. Still others are mentioned in the later cited references. The buffer layer is deposited onto the light-absorbing layer before deposition of the conductive ZnO. In the Figures described herein, for simplicity, the term TCO is meant to include ZnO as well as the stack of buffer layers and ZnO.

For general discussion of these prior art techniques and their drawbacks with regard to mechanical and/or chemical removal of films for series interconnection, see e.g. U.S. Pat. Nos. 6,459,032 and 6,380,477. The traditional scribing method is taught in, e.g. U.S. Pat. Nos. 5,131,954, 4,892,592 and 6,288,325. Also, in U.S. Pat. Nos. 4,724,011 and 4,517,403, there is described an alternative series interconnection scheme without the removal of the semiconductor thin film. These methods rely either on the shorting of the thin film (not a predictable or robust process) or some sort of post-deposition physical treatment using laser or local heating. The teachings of the above cited patents are incorporated herein by reference. Also incorporated herein by reference is a recent comprehensive review article by William N. Shafarman and Lars Stolt, “Cu(InGa)Se₂ Solar Cells,” page 567, Chapter 13, in Handbook of Photovoltaic Science and Engineering, edited by Antonio Lugue and Steven Hegedus, John Wiley & Sons Ltd, England (2003). These references teach the methods known and used in the art for producing CIGS solar devices and the properties of these devices. As set forth in the latter reference and incorporated herein, the term CIGS also includes a compound where some of the selenium may be replaced by sulfur.

In the case of CIGS semiconductor devices particularly, the removal of the material using a laser is not straight-forward. The material melts and it refills the trough (trench) formed by the laser ablation, not leaving a clean Mo surface necessary to make good electrical contact. Further, the presently used, conventional technique of mechanical scribe (relying on the sharp edge of a knife to cut through the layers) for CIGS film is not a robust process, as the quality of the scribe is too sensitive to many parameters, such as the morphology of the Mo film, the surface composition of the Mo film (MoSeₓ is formed during high temperature growth of CIGS), the properties of the CIGS film (including adhesion strength), and smoothness of the movement of the substrate relative to the tip of the knife, and pressure on the knife, etc. The interconnection between front ZnO and the back Mo often shows a large electrical resistance (poor contact). Also, removing the film often leads to excessive loss of the active area of the solar cell due to the need to maintain some margin of safety. Thus, a simpler, alternative method of producing high quality interconnection pathways between the front and back contacts is highly desirable.

In the case of a ZnO front contact, mechanical scribe for interconnect formation is slow, cumbersome, not terribly robust, and requires high capital investment in the equipment (e.g. highly precise movement of the scribe table to ensure consistency and accuracy of plate movement), and difficult to adjust the cut depth for optimal isolation quality without damaging the layers underneath. We have earlier pointed out the debris-induced shorting problem that usually accompanies the scribing technique.

### SUMMARY OF THE INVENTION

A solar PV module comprises an array of serially interconnected PV solar cells on a common substrate, each cell comprising a 1^{st} electrode on said substrate, a light absorbing PV film on the 1^{st} electrode, a 2^{nd} electrode, at least one of said electrodes being light transmitting and wherein the 2^{nd} electrode of the nth solar cell of the array is connected to the 1^{st} electrode of the succeeding (n+1)th cell of the array via a narrow strip of the PV film material which has a substantially higher conductivity than the remaining light absorbing portion of the PV film.

The novel structure of the present invention is achieved by substantially increasing the conductivity of the normally light absorbing PV film in the area of desired electrical contact without significantly affecting its thickness or lateral conformation to the flat substrate. Here, instead of removing strips of the active light absorbing film as presently practiced by PV module manufacturers, the interconnection is accomplished by leaving the film in place, but changing its conductivity so that an effective series interconnection is made from the 1^{st} electrode of one cell to the 2^{nd} electrode of the adjoining cell. The conductivity change is accomplished by incorporating in the light absorbing layer suitable dopants (or alloying elements), which greatly reduces the electrical resistance (resistivity) of the active semiconductor layer in the area of contact so as to make it essentially conductive in the doped areas.

### BRIEF DESCRIPTION OF THE DRAWINGS

FIG. 1 is an elevational view showing a prior art a-Si:H PV module array having serially conducted PV solar cells.

FIG. 2 shows a front elevational view of a prior art un-encapsulated CIGS PV plate having an array of serially connected solar cells.

FIGS. 3-7 are front elevational views depicting one embodiment of a step by step formation of the solar PV module of the present invention wherein the conductive paths are formed using pre-CIGS deposited narrow dopant strips.

FIGS. 8-13 are front elevational views depicting another embodiment of a step by step formation of the solar PV module of the present invention wherein the conductive paths are formed by means of narrow dopant strips applied to the surface of the active film subsequent to its formation followed by heating to diffuse the dopant into the CIGS film.

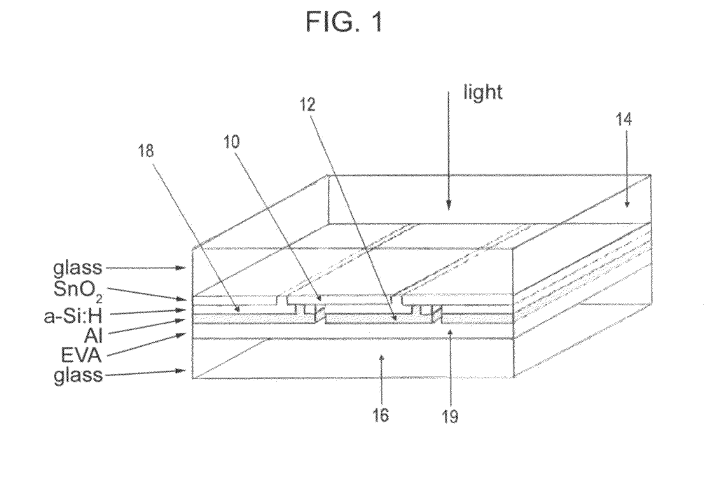

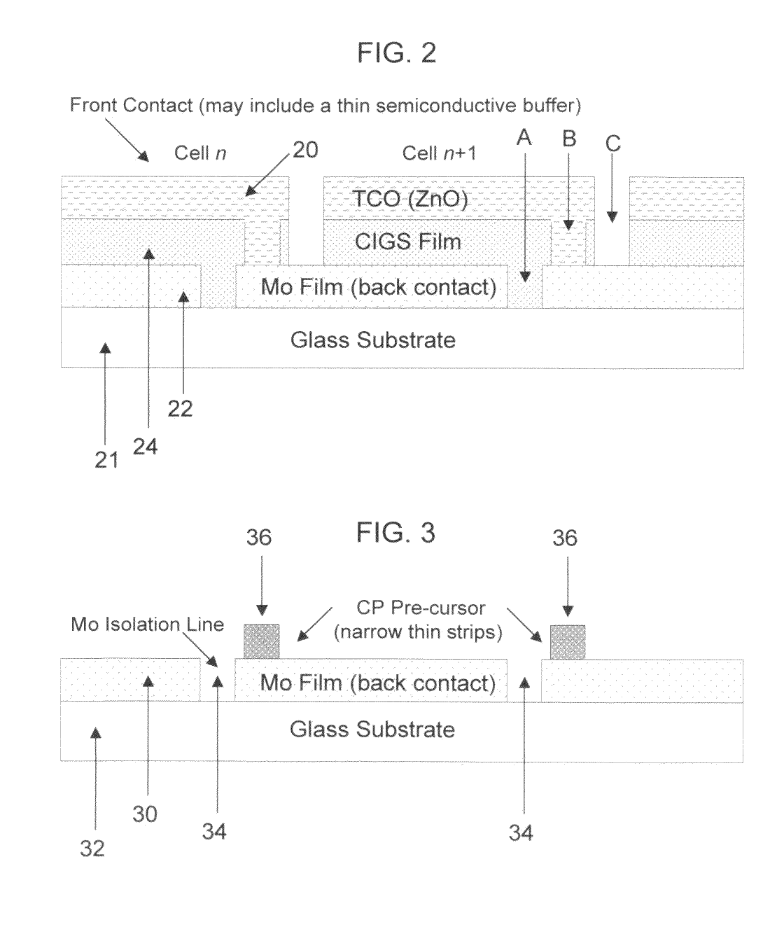

### DETAILED DESCRIPTION OF THE INVENTION

The invention will be described in terms of CIGS PV solar modules. However, it would be obvious to one in the art that light absorbing photovoltaic films other than CIGS can be employed in the practice of the present invention. Further, the term TCO as used herein shall comprise any suitable transparent conductive film including those which include buffer layers as taught, for example, in the cited Shafarman & Stolt reference.

Generally, in accordance with the invention, a solar electric module comprises an array of serially interconnected thin film PV solar cells formed on a substrate. Each cell of the array comprises a back electrode spaced from the back electrode of the adjoining cell, a light absorbing PV film in contact with the back electrode of one cell and extending over at least a portion of the back electrode of the adjoining cell, a TCO front electrode over the PV film, a small portion of which overlies a small portion of the back electrode of the adjoining cell, the TCO front electrodes and the back electrodes of each cell being spaced from the front and back electrodes respectively of the adjoining cells and wherein the normally highly electrically resistive PV film lying between the TCO layer of one cell and the back electrode of the adjoining cell has been modified so as to form a conductive series interconnection between the adjoining cells.

A primary aspect of the present invention is the fact that the CIGS film may be left in place after its deposition but its conductivity in the areas of cell interconnection is changed so that an effective interconnection is made between the 1^{st} electrode (e.g. ZnO transparent electrode) and the adjoining cell's 2^{nd} electrode (e.g. Mo electrode). The conductivity change can be accomplished by incorporating one or more suitable dopants or alloying elements in the CIGS film in the interconnect region. Typically, the dopant(s) change the sheet resistance of the CIGS film from ˜10⁵ Ohm/Square (Ω/□) to under 10 Ω/□. Potential dopants for reducing the sheet resistance in CIGS films are metals, e.g. Cu, Ag, In, Au, Tl, Ga, K and Cs and their compounds such as the selenides, tellurides, sulfides and iodides. Generally, it is more difficult to control and limit the lateral diffusion of metallic dopants as compared with dopants such as Cu₂Se and thus control the width of the interconnect lines of the array. The amount of dopant to be employed i.e. the thickness of the dopant layer and its width is dependent on the thickness of the CIGS absorbing layer.

As an example, for a 1.5 micron thick CIGS film, a narrow strip of dopant compound having a thickness of about 0.5 microns should be adequate to form the low resistance inter-connect pathway. When narrow strips of a Cu₂Se dopant layer are deposited prior to CIGS formation, no further heat treatment is required after formation of the CIGS layer since at the temperature (typically 500° C.-600° C.) of formation of the CIGS, the dopant readily diffuses into the CIGS to form the low resistance inter-connect with only slight broadening of the narrow dopant line. However, when the dopant layer is deposited over an existing CIGS layer, the array must be heat treated to diffuse the dopant into the CIGS layer to form the conductive path. Heating at about 300° C. for 30 minutes is adequate.

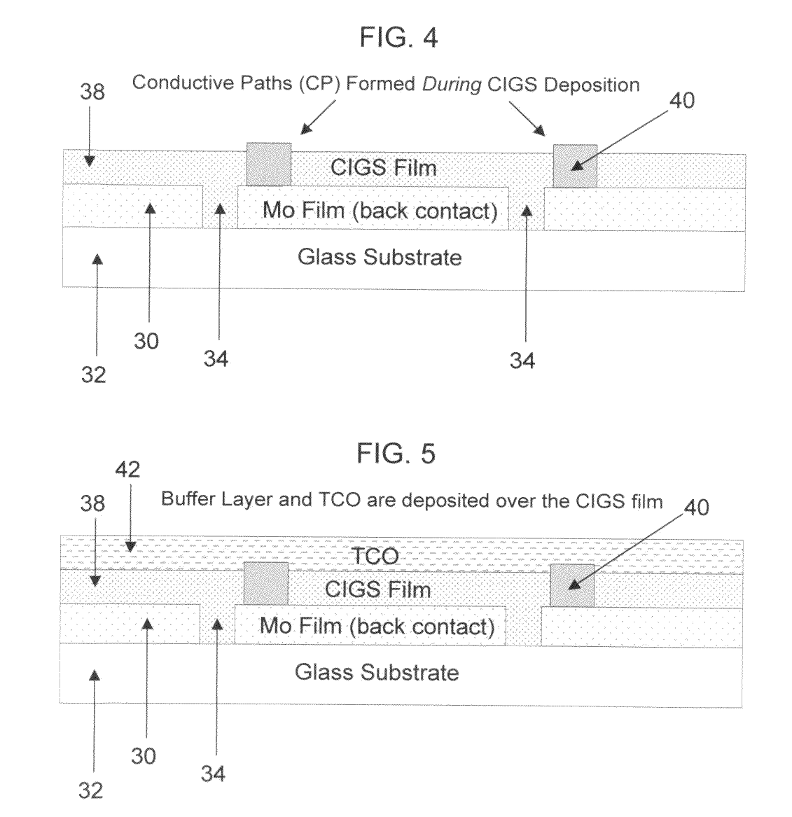

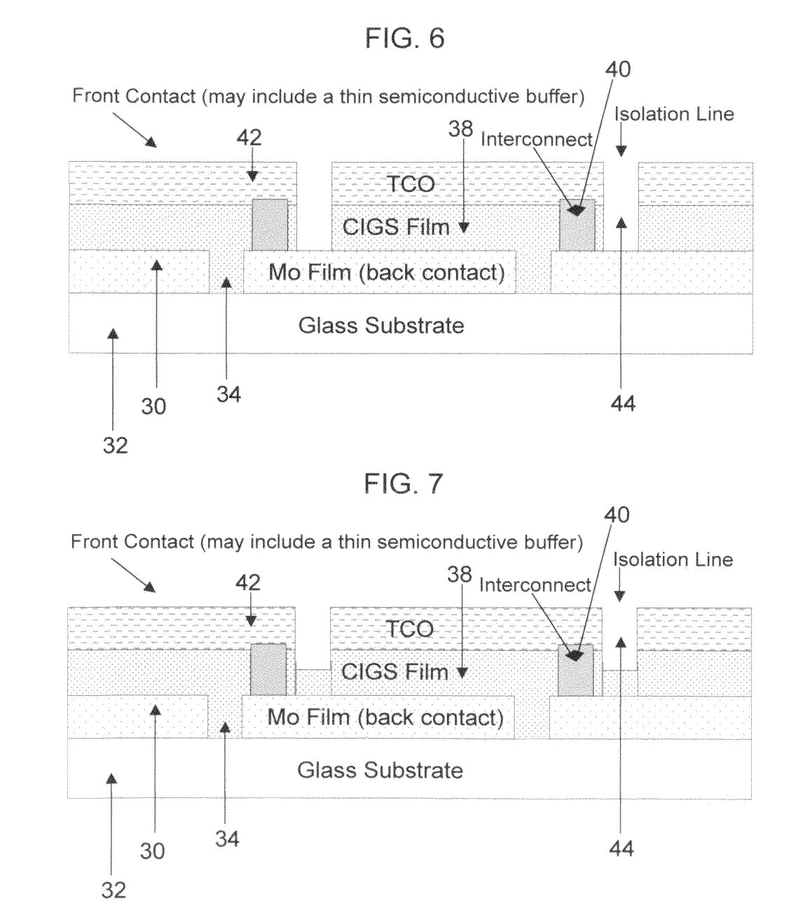

Two embodiments of this invention are illustrated in connection with the drawings. In the first embodiment (FIGS. 3-7), a patterned molybdenum film 30 which acts as the back electrodes of the module is formed on a substrate 32, e.g. glass. The space 34 between adjacent Mo films forms cell isolation lines. A thin, narrow strip of ‘dopant’ material 36 is deposited on the Mo films 30 adjacent the Mo isolation lines 34. Suitable dopants include, but are not limited to Cu₂Se, Cu₂S, and silver-containing alloys. Upon deposition of a continuous CIGS film 38, the dopant 36 diffuses into the CIGS film 38 to form a local, conductive path 40 comprising doped or alloyed CIGS. No specific post-deposition treatment is needed for this process to occur as the conductive paths are formed as part of the natural procedure during formation of the CIGS semiconductor film 38. This is the preferred method of embodiment of this invention. Subsequent to deposition of the CIGS film, a transparent conductive electrode layer 42 (with or without buffer films), e.g. ZnO or CdS/HR ZnO/ZnO is formed over the array. TCO cell isolation lines 44 are then provided through the TCO layer. As long as the isolation lines 44 extend through the TCO layer 42, they may or may not also extend through or partially through the CIGS film 38 (compare FIGS. 6 and 7). The conductive interconnects form a series connection between adjacent cells in the array.

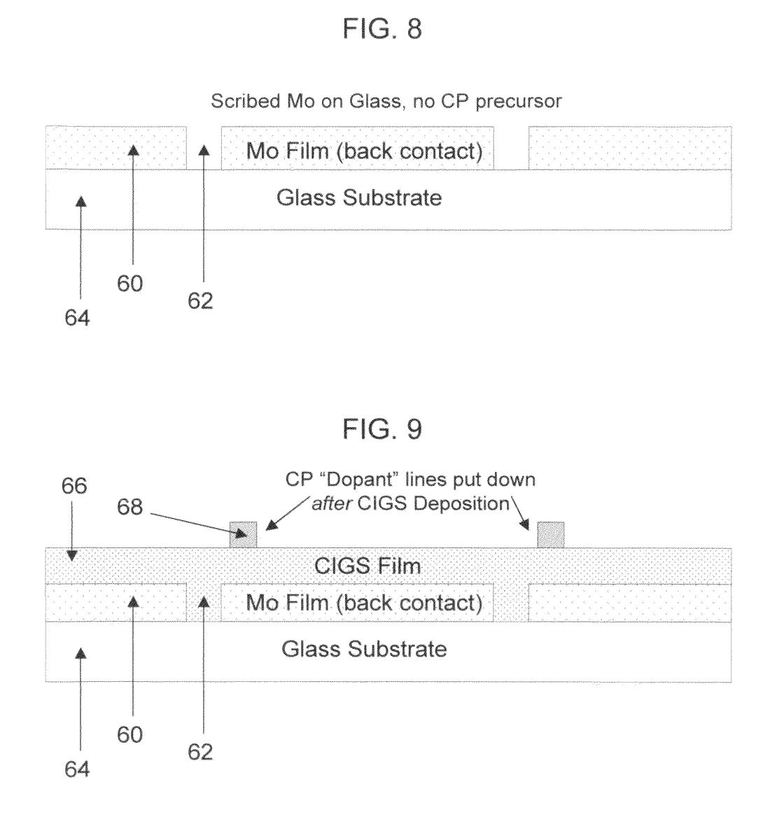

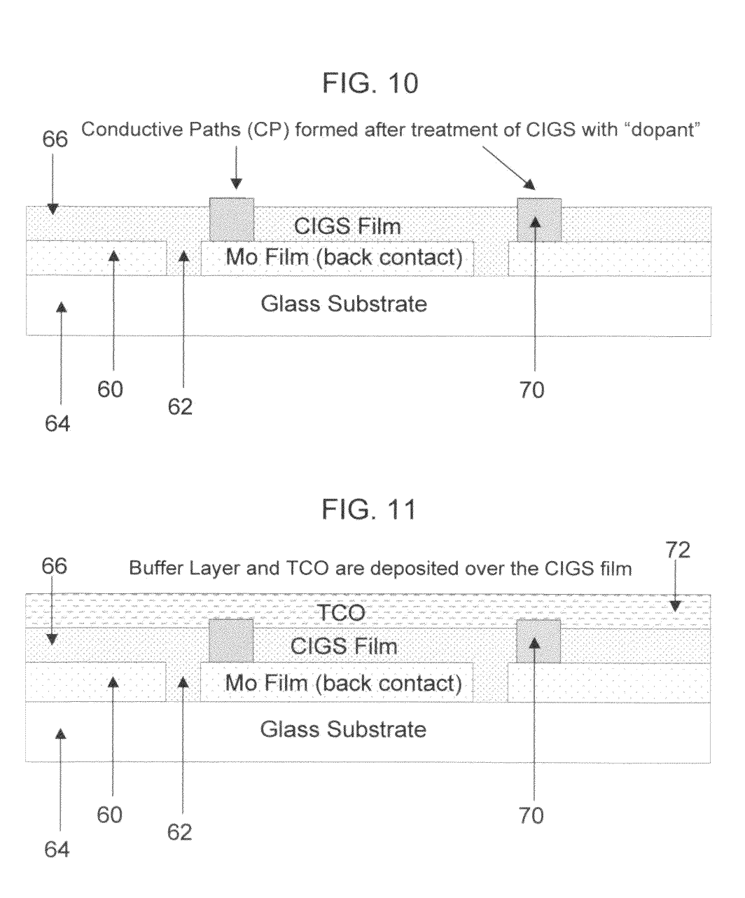

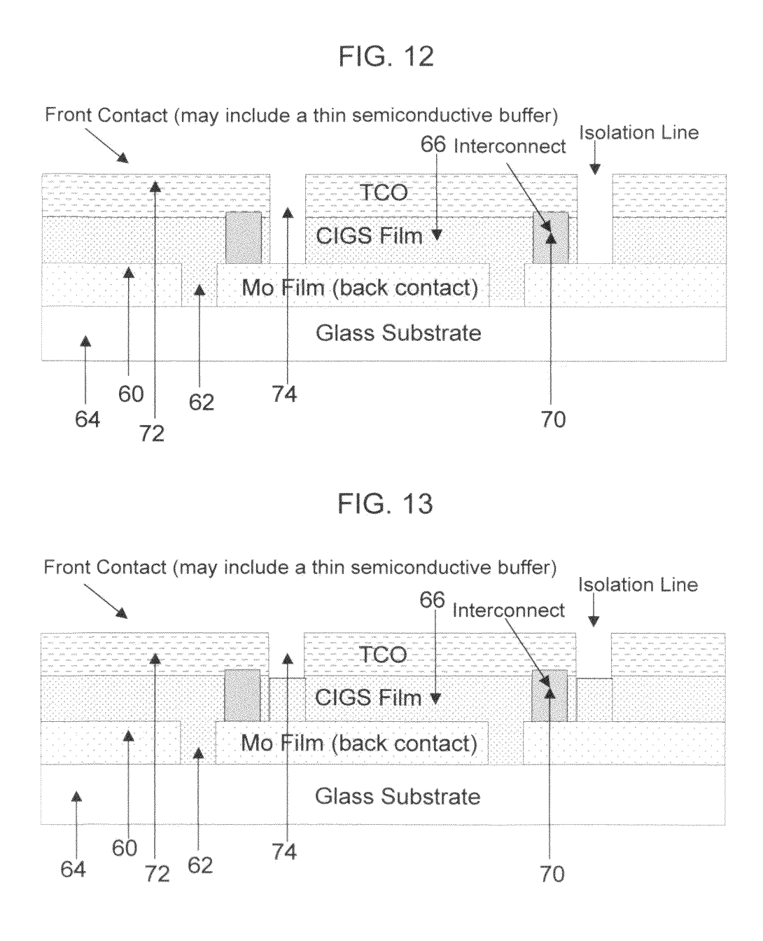

FIGS. 8-13 illustrate a second embodiment for formation of the novel PV module of the present invention. In accordance with this embodiment, a post-deposition modification of the conductivity of the CIGS film at desired locations is accomplished. Here, Mo back electrodes 60 separated by Mo isolation lines 62 are provided on a glass substrate 64. A continuous CIGS film 66 is deposited over the array as is well known in the art. Subsequent to CIGS film 66 formation, narrow dopant lines 68 are deposited on the CIGS film 66 over the Mo electrodes 60 adjacent the Mo isolation lines 62. Subsequent treatment of the sample (heat or laser or thermal-pressure) results in the diffusion of the dopants into the CIGS host to produce narrow, high-conductivity interconnection paths 70 at the desired locations. A TCO film 72 is then deposited over the CIGS film 66. Isolation lines 74 are then formed in the TCO film 72 so as to provide the front electrodes 72 of the cells of the array. The TCO electrode 72 of one cell makes good electrical contact with the Mo back electrode 60 of the adjoining cell either with or without removing any CIGS film. As previously indicated, the TCO film can be a conductive oxide, e.g. ZnO or ZnSnO, and may incorporate a thin buffer layer, e.g. HR ZnO and/or CdS. Further, during isolation of the front electrodes, all, some or none of the underlying CIGS film is removed.

In both the aforementioned embodiments, care should be taken so that there is no substantial lateral diffusion of the dopant that would result in unnecessarily widening the interconnect conductive line and creating dead areas in the otherwise active CIGS material.

Any of the methods well known in the art can be used to deposit materials in their desired locations. These include: screen printing, laser heating, defining the line with a printing head, evaporation through a mask, etc. Further, if the TCO layers are deposited through a mask such that the TCO layer of each cell is isolated form the TCO layer of adjoining cells, no subsequent isolation step would be required and the CIGS layer (including the conductive strips) could remain as a continuous layer.

What is claimed is:

1. A solar PV module comprising an array of serially interconnected PV solar cells on a common substrate, each cell comprising a front electrode and a back electrode spaced from said front electrode, a light absorbing PV film between said front and back electrodes, said front electrode being light transmitting and wherein the front electrode of the nth solar cell of the array overlies and is connected to the back electrode of the succeeding, (n+1)th cell of the array via a portion of said PV film which has been modified to have a substantially higher conductivity than the remainder of the PV film.

2. The PV module recited in claim 1 wherein the light absorbing PV film is a CIGS layer.

3. The PV module recited in claim 2 wherein the high conductivity portion of the PV film is formed by doping a continuous PV film along spaced narrow strips where the front electrode of the nth cell overlies the back electrode of the succeeding (n+1)th cell.

4. The PV module recited in claim 3 wherein the dopant is copper selenide.

5. A PV module comprising an array of serially interconnected thin film CIGS PV solar cells on a substrate, the cells of the array comprising a metal back electrode on said substrate, the back electrode of one cell being spaced from the back electrode of the adjoining cell; a light absorbing CIGS PV film disposed over the back electrodes of the cells in the array and the spaces therebetween, a TCO front electrode layer over said CIGS film, the TCO layer of one cell overlying the back electrode of an adjoining cell and wherein the CIGS film between the TCO layer of one cell and the back electrode of the adjoining cell has been modified by a dopant to form narrow conductive serial interconnect strips between adjacent cells.

6. The PV module recited in claim 5 wherein the TCO layer includes at least one thin buffer.

7. The PV module recited in claim 6 wherein the back electrode is molybdenum, the TCO layer comprises zinc oxide and the conductive interconnect dopant comprises copper selenide, the module further comprising a glass cover plate and a sealant.

8. A method of producing solar PV module which comprises an array of serially interconnected solar cells comprising the steps of depositing a continuous light absorbing, high resistance, PV layer over a substrate having spaced 1^{st} electrodes thereon and doping said PV layer along narrow conductive strips with a doping agent that forms a conductive path through said PV layer along said strips followed by forming spaced 2^{nd} electrodes over said PV layer having said conductive strips so as to provide a serial interconnection between said first electrode of one cell in the array and the 2^{nd} electrode of an adjoining cell.

9. The method recited in claim 8 wherein a narrow strip of dopant is applied adjacent an edge of the spaced 1^{st} electrodes of the array prior to depositing the light absorbing PV film whereby the conductive strips in said film are formed during deposition of said PV film.

10. The method recited in claim 9 wherein the PV film comprises CIGS and the dopant is a member of the group selected from Cu, Ag, In, Tl, Ga, K, Cs and their respective selenides, tellurides, sulfides, and iodides.

11. The method recited in claim 10 wherein the dopant is copper selenide.

12. The method recited in claim 11 wherein the 1^{st} electrodes of the array are molybdenum films on a glass substrate and the 2^{nd} electrodes of the array are TCO thin films.

13. The method recited in claim 12 wherein the TCO layer comprises ZnO and a buffer layer.

14. The method recited in claim 8 wherein the resistant, continuous, light absorbing PV film is deposited over said 1^{st} electrodes and the spaces therebetween and narrow strips of dopant are thereafter deposited over said PV film and the array is then heat treated to cause the dopant to diffuse into said PV film so as to create said narrow conductive paths therein.

15. The method recited in claim 14 wherein the PV film comprises CIGS and the dopant is a member of the group selected from Cu, Ag, In, Tl, Ga, K, Cs and their respective selenides, tellurides, sulfides and iodides.

16. The method recited in claim 15 wherein the dopant is copper selenide.

17. The method recited in claim 16 wherein the 1^{st} electrodes of the array are molybdenum films on a glass substrate and the 2^{nd} electrodes of the array are TCO electrodes.

18. The method recited in claim 17 wherein the TCO layer comprises ZnO and a buffer layer.

19. The method recited in claim 18 wherein the buffer layer comprises copper sulfide.

20. The method recited in claim 13 wherein the buffer layer comprises copper sulfide.
